(19) United States
(12) Patent Application Publication
(10) Pub. No.: US 2008/0061862 A1
(43) Pub. Date: Mar. 13, 2008

(54) Electronic Circuit Arrangement With Active Control During The Reception Of A Received Electrical Signal

(75) Inventors: Rainer Bartenschlager, Kaufbeuren (DE); Martin Brox, Munchen (DE); Thomas Hein, Munchen (DE); Ullrich Menczigar, Vaterstetten (DE)

Correspondence Address: JENKINS, WILSON, TAYLOR & HUNT, P. A., 3100 TOWER BLVD., Suite 1200, DURHAM, NC, 27707, US

(73) Assignee: QIMONDA AG, MUNICH (DE)

(21) Appl. No.: 11/664,011

(22) PCT Filed: Oct. 19, 2005
(86) PCT No.: PCT/EP05/11248

§ 371 Date: Nov. 5, 2007

(30) Foreign Application Priority Data
Nov. 12, 2004 (DE) 10 2004 054 819.6

(51) Int. Cl. H03K 3/26

(52) U.S. Cl. 327/509

(57) ABSTRACT

The invention creates an electronic circuit arrangement for receiving a received electrical signal (101) with a first receiving device (100), a second receiving device (200) and a comparator unit (301) for comparing a second signal difference (207), output by the second receiving device (200), with a target value signal (303) and for outputting a control signal (305) in dependence on the comparison, wherein the control signal (305) controls both the first receiving device (100) and the second receiving device (200) into a respective operating point in such a manner that the amplified second signal difference (207) is held at a level of the target value signal (303) and a first signal difference (107) output from the first receiving device (100) supplies with high accuracy a measure of the received signal (101) with respect to a predetermined reference signal (103).

The present invention generally relates to circuit arrangements for receiving electrical signals, particularly voltage signals, and for outputting digital signal values which are dependent on the received electrical signals, and specifically relates to a receiver device with active control.

In particular, the invention is directed towards an electronic circuit arrangement for receiving a received electrical signal which has a first receiving device with a received signal input unit for inputting the received electrical signal to be processed, a reference signal input unit for inputting a reference signal, a first reference amplifier unit for amplifying a first signal difference between the received signal and the reference signal and a first output unit for outputting the first signal difference, amplified by the first signal amplifier unit, between the received signal and the reference signal.

During the reception of received electrical signals, the problem occurs that these must be compared very precisely with a reference signal in the electronic receiving device. With the introduction of differential amplifiers for transmitting data with double the data rate (DDR), in particular, receiving devices have become necessary which amplify such transmission signals which occur, for example, in the operation of dynamic random access memories (DRAM). In this context, a received electrical signal is compared with a reference voltage supplied externally, the reference voltage typically being set to half the operating voltage of the electronic circuit arrangement.

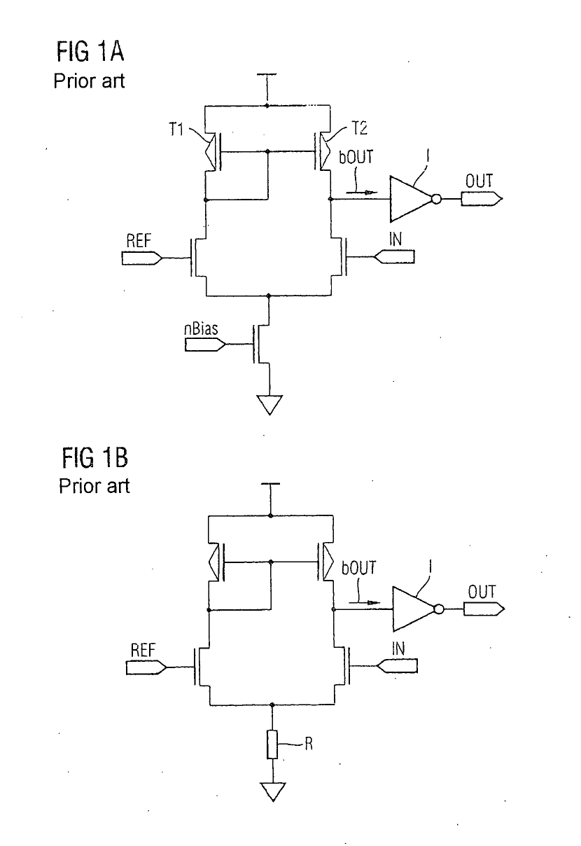

FIGS. 1(a) and 1(b) illustrate conventional circuit arrangements of such an input stage. FIG. 1(a) shows a differential amplifier transistor pair T1 and T2 consisting of n-FET (field effect transistors). Furthermore, a current balancing unit consisting of p-FET units is also used for amplification in the circuit arrangement. A gate bias (n-bias) of one n-FET can either be a controlled voltage, where the n-FET then operates as a controlled current source, or can be simply operated by a digital level where the n-FET then only acts as enabling device.

FIG. 1(b) shows a further differential amplifier circuit according to the prior art. In this arrangement, the current source (n-bias) shown in FIG. 1(a) is replaced by a simple resistor R.

The circuit arrangements described above with reference to FIGS. 1(a) and (b) allow input signals IN to be compared with reference signals REF in a simple manner. This provides an inverted bOUT or non-inverted OUT output signal. However, such conventional circuit arrangements as described by means of FIGS. 1(a) and (b) have significant disadvantages. A main disadvantage of the conventional circuit arrangements consists in that when the reference voltage REF drops to a value which is too low, a functionality of the receiving n-FET transistor pairs is impaired. Specifically, the propagation delay for a falling, edge, i.e. in the case V(IN)<V_{REF} becomes considerably longer than the delay for a rising edge, i.e. for the case V(IN)>V_{REF}. This results in an unwanted, non-symmetrical behaviour of the receiving device.

It is also disadvantageous that the voltage bOUT which drives the output inverter I (see FIG. 1(a), (b)) is not well defined. The choice of switching point of the output inverter I is therefore extremely critical.

Furthermore, it is inexpedient that variations with respect to the production process, the applied voltages and the temperature range cannot be corrected. In the text which follows, such variations will be called PVT (process/voltage/temperature) variations.

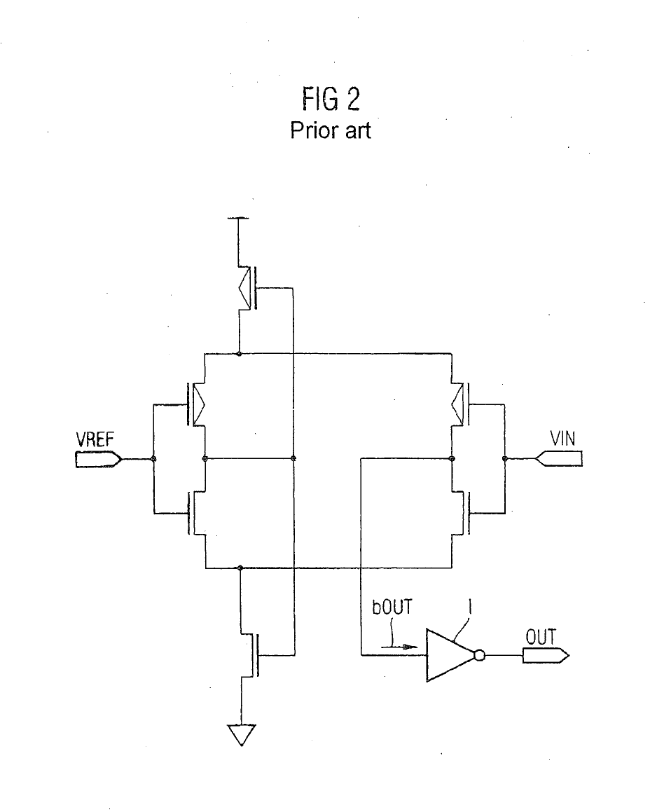

To solve the above-mentioned problems, it has been proposed in the prior art to use a ‘self-biased receiver’ which is illustrated in FIG. 2 and is disclosed in the printed document U.S. Pat. No. 4,937,476. In the circuit arrangement shown in FIG. 2, the input stage consists of an n-FET connected in series with a P-FET, in such a manner that the operation is improved at a low reference voltage V_{REF}. However, the disclosed circuit arrangement has the disadvantage that the output voltage bOUT can deviate from half the operating voltage Vdd/2 even when the input voltage corresponds to the reference voltage, i.e. when V(IN)=V_{REF} applies. The disadvantage thus exists that it is difficult to control the output inverter I in the case of PVT variations.

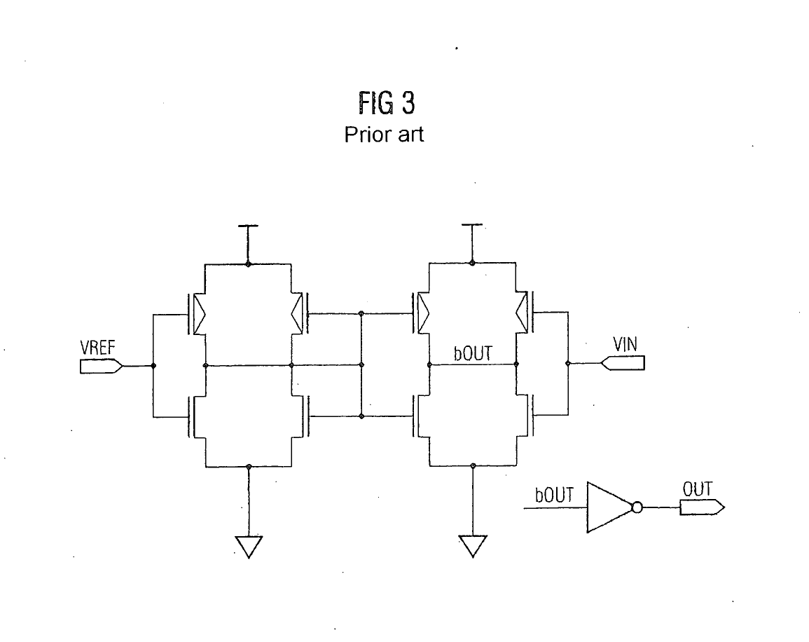

FIG. 3 shows a further conventional circuit arrangement which is described in the publication “IEEE Journal of Solid-State Circuits, volume 35, No. 2, February 2000, pages 149-162”. This receiver device uses a mixed n- and p-FET receiving stage in order to improve the behaviour at a low reference voltage V_{REF}.

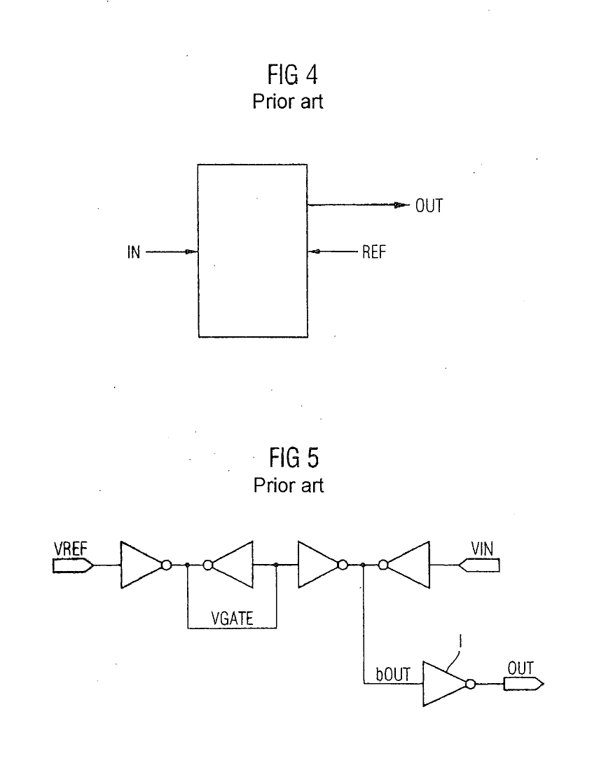

FIG. 4 shows a schematic block diagram of the conventional receiver device. In this arrangement, the input voltage IN is compared with the reference voltage REF in order to obtain an output voltage OUT.

FIG. 5 shows the conventional circuit arrangement in greater detail, the triangles shown identifying amplifier stages and inverters, respectively. The receiver concept shown in FIG. 5 comprises two inverter pairs which operate back to back. If the input voltage V(IN) corresponds to the reference voltage V_{REF}, i.e. if V(IN)=V_{REF} applies, the output voltage bOUT corresponds to the gate voltage VGate, i.e. bOUT=VGate applies.

If then, for example, the received signal of V(IN) exceeds the reference voltage V_{REF}, i.e. if V(IN)>V_{REF}, bOUT decreases and thus the output of the inverter I goes to a high level OUT. Disadvantageously, however, like the “self-biased” receiver described above, the output level bOUT is not precisely defined.

It is an object of the present invention, therefore, to provide a circuit arrangement for receiving a received electrical signal in which process variations, temperature variations, voltage variations and variations in the reference voltage do not have any influence on an output signal output from the electronic circuit arrangement.

This object is achieved by an electronic circuit arrangement for receiving a received electrical signal having the features of patent Claim 1.

Further embodiments of the invention can be obtained from the subclaims.

An essential concept of the invention consists in designing a receiving device for receiving a received electrical input signal in duplicate, wherein a first receiving device compares a received electrical signal to be processed with a reference voltage whilst identical first and second reference signals are supplied to a second receiving device, wherein the operating points both of the first receiving device and of the second receiving device are controlled by the output signal of the second receiving device into one operating point, so that the signal processing provided in the first receiving device operates independently of fluctuations in the reference voltage and/or independently of process, voltage and/or voltage and/or temperature variations (PVT variations).

The first and second receiving devices advantageously consist of identical circuit components having an identical circuit structure.

According to a main aspect of the present invention, the electronic circuit arrangement for receiving a received electrical signal essentially has the following:

a) a first receiving device which includes:

a1) a received signal input unit for inputting the received electrical signal to be processed;

a2) a reference signal input unit for inputting a reference signal;

a3) a first differential amplifier unit for amplifying a first signal difference between the received signal and the reference signal; and

a4) a first output unit for outputting the first signal difference, amplified by the first differential amplifier unit, between the received signal and the reference signal;

b) a second receiving device which includes:

b1) a first reference signal input unit for inputting a first reference signal;

b2) a second reference signal input unit for inputting a second reference signal;

b3) a second differential amplifier unit for amplifying a second signal difference between the first reference signal and the second reference signal, and

b4) a second output unit for outputting the second signal difference, amplified by the second differential amplifier unit, between the first reference signal and the second reference signal, and

c) a comparator unit for comparing the second signal difference, amplified by the second differential amplifier unit, between the first reference signal and the second reference signal with a target value signal and for outputting a control signal in dependence on the comparison,

d) wherein the control signal controls both the first receiving device and the second receiving device into a respective operating point in such a manner that the amplified second signal difference is held at a level of the target value signal.

The subclaims contain further preferred developments of the present invention.

According to a preferred development of the present invention, the received electrical signal to be processed and/or the reference signal are voltage signals. It is also advantageous that the first reference signal and the second reference signal are voltage signals.

According to a further preferred development of the present invention, the first receiving device and the second receiving device are constructed identically from identical circuit components.

A preferred operation of the circuit arrangement according to the invention is carried out in such a manner that the reference signal, the first reference signal and the second reference signal are identical.

According to another preferred development of the present invention, a target value signal of a voltage level of half the operating voltage Vdd/2 of the electronic circuit arrangement is predetermined for the comparator unit for comparing the second signal difference, amplified by the second differential amplifier unit, between the first reference signal and the second reference signal with the target value signal.

According to a further preferred development of the present invention, the first receiving device and the second receiving device, which are constructed identically from identical circuit components, are arranged on a common circuit chip.

It is advantageous if the reference signal, the first reference signal and/or the second reference signal have a voltage level of half the operating voltage Vdd/2 of the electronic circuit arrangement.

In the text which follows, an illustrative embodiment of the present invention will be described with reference to the drawings, in which:

FIG. 1(a) shows a conventional differential amplifier arrangement with an n-FET differential amplifier transistor pair, using a current balancing circuit;

FIG. 1(b) is a conventional circuit arrangement in which the current balancing circuit is replaced by a resistor;

FIG. 2 is an example of a conventional “self-biased” receiver;

FIG. 3 is a receiver device with a mixed n- and p-FET receiving stage;

FIG. 4 is a schematic block diagram of the receiver device shown in FIG. 3;

FIG. 5 is a circuit equivalence diagram consisting of inverters for the receiver device shown in FIG. 3;

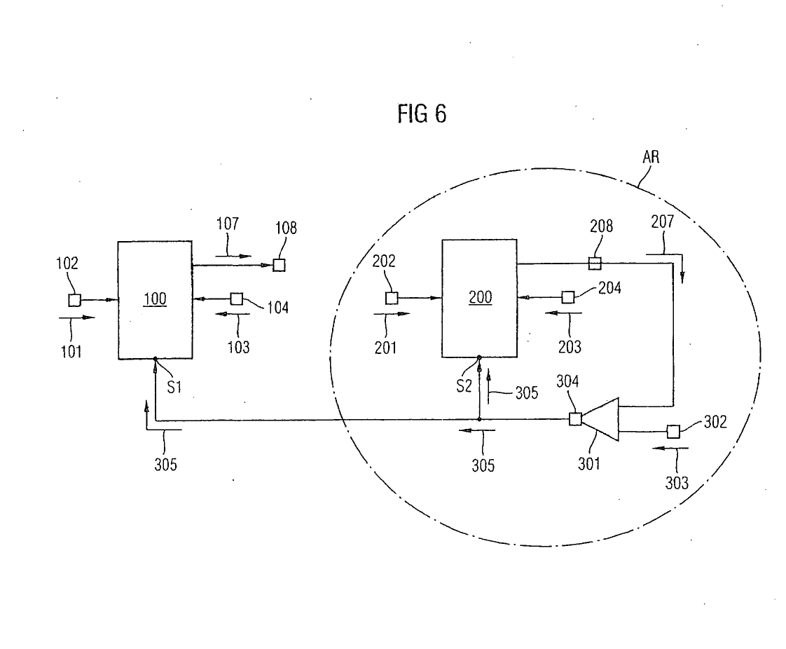

FIG. 6 is a circuit arrangement according to the invention for receiving a received electrical signal according to a preferred illustrative embodiment of the present invention; and

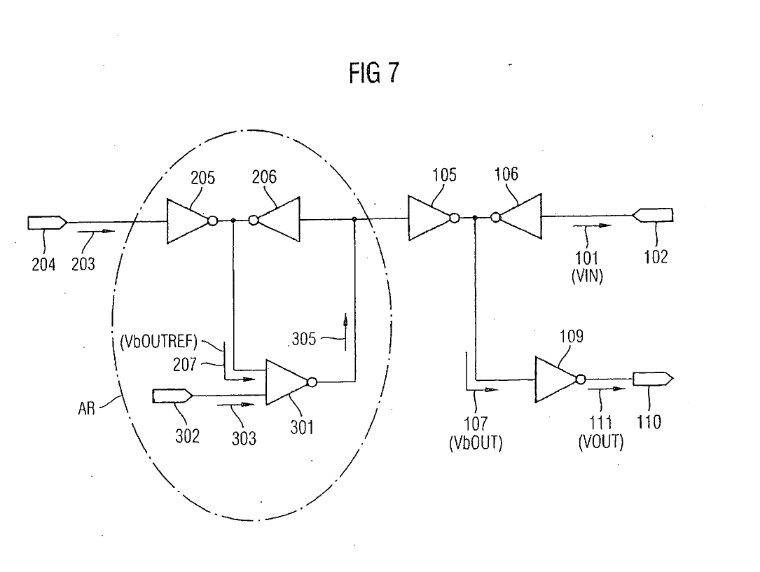

FIG. 7 is an equivalence circuit diagram consisting of inverters for the circuit arrangement shown in FIG. 6.

In the figures, identical reference symbols designate identical or functionally identical components or steps.

In FIG. 6, a reference symbol 100 designates a first receiving device which has a received signal input unit 102 for inputting a received electrical signal 101 to be processed, a reference signal input unit 104 for inputting a reference signal 103, a first differential amplifier unit 105, 106 (described with reference to FIG. 7 in the text which follows) for amplifying a first signal difference 107 between the received signal 101 and the reference signal 103 and a first output unit 108 for outputting the first signal difference 107, amplified by the first differential amplifier unit 105, 106 between the received signal 101 and the reference signal 103. Furthermore, the first receiving device 100 can be supplied via a control terminal S1 with a control signal 305 for controlling or setting the operating point of the receiving device 100.

According to the invention, the circuit arrangement according to the preferred illustrative embodiment of the present invention, described here, has an active control device AR (dashed line in FIG. 6). The active control device AR shown in FIG. 6 essentially comprises a second receiving device 200 and a comparator unit 301.

The receiving device 200 has a first reference signal input unit 202 for inputting a first reference signal 201, a second reference signal input unit 204 for inputting a second reference signal 203, a second differential amplifier unit 205, 206 (described with reference to FIG. 7 in the text which follows) for amplifying a second signal difference 207 between the first reference signal 201 and the second reference signal 203 and a second output unit 208 for outputting the second signal difference, amplified by the second differential amplifier unit 205, 206, between the first reference signal 201 and the second reference signal 203. As in the case of the first receiving device 100, the second receiving device 200 can also be supplied with the control signal 205. For this purpose, the second receiving device 200 has a control terminal S2 via which the operating point of the second receiving device 200 can be adjusted.

The comparator unit 301 has a target value signal input unit 302 for inputting a target value signal 303 and a control signal output unit 304 for outputting the control signal 305 which is supplied to the first receiving device 100 via the control terminal S1 and to the second receiving device 200 via the control terminal S2.

The target value signal 303 is preferably set to a voltage level which corresponds to half the operating voltage of the entire circuit arrangement (i.e. a voltage level Vdd/2). Furthermore, the first reference voltage 201 and the second reference voltage 203 which are supplied to the second receiving device 200 are set to an equal voltage level which also corresponds to the voltage level of the reference signal 103 which is supplied to the first receiving device 100 via its reference signal input unit 104.

The first signal difference 107 output via the first output unit 108 is used as output signal of the circuit arrangement, in such a manner that it represents a digital value which changes between two states in dependence on how the received signal 101 to be processed is located with reference to the reference signal 103.

In contrast, the second signal difference 207 output from the second receiving device 200 via its second output unit 208 is fixed by the circuit arrangement according to the invention since the second receiving device is supplied with two identical reference signals, i.e. the first reference signal 201 and the second reference signal 203. The second signal difference 207 is thus fixed to a value which corresponds to the target value signal 303. The target value signal 303 which is supplied to the comparator unit 301 via its target value signal input terminal 302 is preferably set to a voltage level which corresponds to half the operating voltage of the entire circuit arrangement, i.e. to a voltage level of Vdd/2.

Independently of the first and second reference signals 201, 203 provided, the gate of the output inverter unit 107 is held at such a medium voltage level Vdd/2 in order to be able to operate at an optimum operating point.

FIG. 7 shows the circuit arrangement shown in FIG. 6 as an equivalent circuit consisting of inverters 105, 106, 205, 206, 301 and 109. A dot-dashed line identifies the active control device AR which includes the second receiving device 200 and the comparator unit 301. In this arrangement, the receiving device 200 (see FIG. 6) with the second differential amplifier unit 205, 206 generates an internal reference voltage VGateREF which corresponds to the control variable 305. The receiving device 200 controls the control variable 305 in such a manner that the following applies: V(bOUTREF)=Vdd/2, i.e. that the control signal 305 controls both the first receiving device 100 and the second receiving device 200 into a respective operating point in such a manner that the amplified second signal difference 207 is held at a level of the target value signal 303.

As can be seen from FIG. 7, the receiving device 200 (active control device AR) ensures that the first signal difference 107 (VbOUT) corresponds to half the operating voltage (Vdd/2) when the voltage level of the received signal 101 corresponds to that of the reference signal 103 (see FIG. 6).

In this circuit design, the second signal difference 107, i.e. the voltage signal VbOUT is controlled extremely precisely and the switching point of the output inverter 109 can be set to half the operating voltage Vdd/2 in a simple manner. If the received signal V(IN) drops below the reference voltage V_{REF}, the signal difference 107 (VbOUT) is pulled above Vdd/2 via the received p-FET. In consequence, the output signal 111 (VOUT) is switched to a low level by means of the output inverter 109, the output inverter 109 having its switching point at Vdd/2. When V(IN) rises to a value above V_{REF}, VbOUT, i.e. the first signal difference 107, is pulled below Vdd/2 and, in consequence, the output signal 111 which is output via the output terminal 110 is switched to a high level (VOUT at a high digital level).

It is advantageously possible to provide energy saving for the entire circuit arrangement by means of the following measures:

(i) the internal reference voltage VGateREF does not need to be generated individually for each input terminal but can be divided between an arbitrary number of input terminals (e.g. 4, 8, 16, . . . );

(ii) if the circuit arrangement is in a state in which it is not required that input receiving devices operate (power-down, non-write, . . . ), the control signal 305 (VGateREF) can be separated from the first differential amplifier unit 105; and

(iii) the receiving stage for the reference voltage V_{REF} can be designed by using dimensions which are scaled down, for example each width dimension of the device can be halved. In this state, VGateREF, i.e. the control signal 305 is generated correctly but the current into the V_{REF} stage is reduced to half the value of the current which would flow if the first receiving device 100 and the second receiving device 200 were constructed from identical circuit components.

It is advantageous to arrange the first receiving device 100 and the second receiving device 200 on a common circuit chip.

The target value signal 303 input into the comparator unit 301 can be generated internally in the circuit chip or predetermined externally. The circuit arrangement according to the invention thus becomes independent of fluctuations in the reference voltage supplied to the first receiving device 100 (with regard to fluctuations of the first reference signal 103) and independent of process variations which occur during a production of receiving devices since the first and second receiving devices 100, 200 are produced from identical circuit components in the same process.

Reference is made to the introduction to the description with respect to the conventional circuit arrangements shown in FIGS. 1 to 5.

Although the present invention has been described above by means of preferred illustrative embodiments, it is not restricted to these but can be modified in many ways.

In addition, the invention is not restricted to the possible applications mentioned.

### LIST OF REFERENCE DESIGNATIONS

In the figures, identical reference symbols designate identical or functionally identical components or steps.
100 Receiving device
101 Received signal
102 Received signal input unit
103 Reference signal
104 Reference signal input unit
105, 106 First differential amplifier unit
107 First signal difference
108 First output unit
109 Inverter unit
110 Output terminal
111 Output signal
200 Receiving device
201 First reference signal
202 Reference signal input unit
203 Second reference signal
204 Reference signal input unit
205, 206 Second differential amplifier unit
207 Second signal difference
208 Second output unit
301 Comparator unit
303 Target value signal
305 Control signal
S1 First control terminal
S2 Second control terminal
Vdd/2 Half operating voltage
AR Control device

### DESCRIPTION

Electronic circuit arrangement with active control during the reception of a received electrical signal

The present invention generally relates to circuit arrangements for receiving electrical signals, particularly voltage signals, and for outputting digital signal values which are dependent on the received electrical signals, and specifically relates to a receiver device with active control.

In particular, the invention is directed towards an electronic circuit arrangement for receiving a received electrical signal which has a first receiving device with a received signal input unit for inputting the received electrical signal to be processed, a reference signal input unit for inputting a reference signal, a first reference amplifier unit for amplifying a first signal difference between the received signal and the reference signal and a first output unit for outputting the first signal difference, amplified by the first signal amplifier unit, between the received signal and the reference signal.

During the reception of received electrical signals, the problem occurs that these must be compared very precisely with a reference signal in the electronic receiving device. With the introduction of differential amplifiers for transmitting data with double the data rate (DDR), in particular, receiving devices have become necessary which amplify such transmission signals which occur, for example, in the operation of dynamic random access memories (DRAM). In this context, a received electrical signal is compared with a reference voltage supplied externally, the reference voltage typically being set to half the operating voltage of the electronic circuit arrangement.

FIGS. 1(a) and 1(b) illustrate conventional circuit arrangements of such an input stage. FIG. 1(a) shows a differential amplifier transistor pair T1 and T2 consisting of n-FET (field effect transistors). Furthermore, a current balancing unit consisting of p-FET units is also used for amplification in the circuit arrangement. A gate bias (n-bias) of one n-FET can either be a controlled voltage, where the n-FET then operates as a controlled current source, or can be simply operated by a digital level where the n-FET then only acts as enabling device.

FIG. 1(b) shows a further differential amplifier circuit according to the prior art. In this arrangement, the current source (n-bias) shown in FIG. 1(a) is replaced by a simple resistor R.

The circuit arrangements described above with reference to FIGS. 1(a) and (b) allow input signals IN to be compared with reference signals REF in a simple manner. This provides an inverted bOUT or non-inverted OUT output signal. However, such conventional circuit arrangements as described by means of FIGS. 1(a) and (b) have significant disadvantages. A main disadvantage of the conventional circuit arrangements consists in that when the reference voltage REF drops to a value which is too low, a functionality of the receiving n-FET transistor pairs is impaired. Specifically, the propagation delay for a falling edge, i.e. in the case V(IN)<V_{REF} becomes considerably longer than the delay for a rising edge, i.e. for the case V(IN)>V_{REF}. This results in an unwanted, non-symmetrical behaviour of the receiving device.

It is also disadvantageous that the voltage bOUT which drives the output inverter I (see FIG. 1(a), (b)) is not well defined. The choice of switching point of the output inverter I is therefore extremely critical.

Furthermore, it is inexpedient that variations with respect to the production process, the applied voltages and the temperature range cannot be corrected. In the text which follows, such variations will be called PVT (process/voltage/temperature) variations.

To solve the above-mentioned problems, it has been proposed in the prior art to use a ‘self-biased receiver’ which is illustrated in FIG. 2 and is disclosed in the printed document U.S. Pat. No. 4,937,476. In the circuit arrangement shown in FIG. 2, the input stage consists of an n-FET connected in series with a p-FET, in such a manner that the operation is improved at a low reference voltage V_{REF}. However, the disclosed circuit arrangement has the disadvantage that the output voltage bOUT can deviate from half the operating voltage Vdd/2 even when the input voltage corresponds to the reference voltage, i.e. when V(IN)=V_{REF} applies. The disadvantage thus exists that it is difficult to control the output inverter I in the case of PVT variations.

FIG. 3 shows a further conventional circuit arrangement which is described in the publication “IEEE Journal of Solid-State Circuits, volume 35, No. 2, February 2000, pages 149-162”. This receiver device uses a mixed n- and p-FET receiving stage in order to improve the behaviour at a low reference voltage V_{REF}.

FIG. 4 shows a schematic block diagram of the conventional receiver device. In this arrangement, the input voltage IN is compared with the reference voltage REF in order to obtain an output voltage OUT.

FIG. 5 shows the conventional circuit arrangement in greater detail, the triangles shown identifying amplifier stages and inverters, respectively. The receiver concept shown in FIG. 5 comprises two inverter pairs which operate back to back. If the input voltage V(IN) corresponds to the reference voltage V_{REF}, i.e. if V(IN)=V_{REF} applies, the output voltage bOUT corresponds to the gate voltage VGate, i.e. bOUT=VGate applies.

If then, for example, the received signal of V(IN) exceeds the reference voltage V_{REF}, i.e. if V(IN)>V_{REF}, bOUT decreases and thus the output of the inverter I goes to a high level OUT. Disadvantageously, however, like the “self-biased” receiver described above, the output level bOUT is not precisely defined.

It is an object of the present invention, therefore, to provide a circuit arrangement for receiving a received electrical signal in which process variations, temperature variations, voltage variations and variations in the reference voltage do not have any influence on an output signal output from the electronic circuit arrangement.

This object is achieved by an electronic circuit arrangement for receiving a received electrical signal having the features of patent Claim 1.

Further embodiments of the invention can be obtained from the subclaims.

An essential concept of the invention consists in designing a receiving device for receiving a received electrical input signal in duplicate, wherein a first receiving device compares a received electrical signal to be processed with a reference voltage whilst identical first and second reference signals are supplied to a second receiving device, wherein the operating points both of the first receiving device and of the second receiving device are controlled by the output signal of the second receiving device into one operating point, so that the signal processing provided in the first receiving device operates independently of fluctuations in the reference voltage and/or independently of process, voltage and/or voltage and/or temperature variations (PVT variations).

The first and second receiving devices advantageously consist of identical circuit components having an identical circuit structure.

According to a main aspect of the present invention, the electronic circuit arrangement for receiving a received electrical signal essentially has the following:

a) a first receiving device which includes:

a1) a received signal input unit for inputting the received electrical signal to be processed;

a2) a reference signal input unit for inputting a reference signal;

a3) a first differential amplifier unit for amplifying a first signal difference between the received signal and the reference signal; and

a4) a first output unit for outputting the first signal difference, amplified by the first differential amplifier unit, between the received signal and the reference signal;

b) a second receiving device which includes:

b1) a first reference signal input unit for inputting a first reference signal;

b2) a second reference signal input unit for inputting a second reference signal;

b3) a second differential amplifier unit for amplifying a second signal difference between the first reference signal and the second reference signal, and

b4) a second output unit for outputting the second signal difference, amplified by the second differential amplifier unit, between the first reference signal and the second reference signal, and

c) a comparator unit for comparing the second signal difference, amplified by the second differential amplifier unit, between the first reference signal and the second reference signal with a target value signal and for outputting a control signal in dependence on the comparison,

d) wherein the control signal controls both the first receiving device and the second receiving device into a respective operating point in such a manner that the amplified second signal difference is held at a level of the target value signal.

The subclaims contain further preferred developments of the present invention.

According to a preferred development of the present invention, the received electrical signal to be processed and/or the reference signal are voltage signals. It is also advantageous that the first reference signal and the second reference signal are voltage signals.

According to a further preferred development of the present invention, the first receiving device and the second receiving device are constructed identically from identical circuit components.

A preferred operation of the circuit arrangement according to the invention is carried out in such a manner that the reference signal, the first reference signal and the second reference signal are identical.

According to another preferred development of the present invention, a target value signal of a voltage level of half the operating voltage Vdd/2 of the electronic circuit arrangement is predetermined for the comparator unit for comparing the second signal difference, amplified by the second differential amplifier unit, between the first reference signal and the second reference signal with the target value signal.

According to a further preferred development of the present invention, the first receiving device and the second receiving device, which are constructed identically from identical circuit components, are arranged on a common circuit chip.

It is advantageous if the reference signal, the first reference signal and/or the second reference signal have a voltage level of half the operating voltage Vdd/2 of the electronic circuit arrangement.

In the text which follows, an illustrative embodiment of the present invention will be described with reference to the drawings, in which:

FIG. 1(a) shows a conventional differential amplifier arrangement with an n-FET differential amplifier transistor pair, using a current balancing circuit;

FIG. 1(b) is a conventional circuit arrangement in which the current balancing circuit is replaced by a resistor;

FIG. 2 is an example of a conventional “self-biased” receiver;

FIG. 3 is a receiver device with a mixed n- and p-FET receiving stage;

FIG. 4 is a schematic block diagram of the receiver device shown in FIG. 3;

FIG. 5 is a circuit equivalence diagram consisting of inverters for the receiver device shown in FIG. 3;

FIG. 6 is a circuit arrangement according to the invention for receiving a received electrical signal according to a preferred illustrative embodiment of the present invention; and

FIG. 7 is an equivalence circuit diagram consisting of inverters for the circuit arrangement shown in FIG. 6.

In the figures, identical reference symbols designate identical or functionally identical components or steps.

In FIG. 6, a reference symbol 100 designates a first receiving device which has a received signal input unit 102 for inputting a received electrical signal 101 to be processed, a reference signal input unit 104 for inputting a reference signal 103, a first differential amplifier unit 105, 106 (described with reference to FIG. 7 in the text which follows) for amplifying a first signal difference 107 between the received signal 101 and the reference signal 103 and a first output unit 108 for outputting the first signal difference 107, amplified by the first differential amplifier unit 105, 106 between the received signal 101 and the reference signal 103. Furthermore, the first receiving device 100 can be supplied via a control terminal S1 with a control signal 305 for controlling or setting the operating point of the receiving device 100.

According to the invention, the circuit arrangement according to the preferred illustrative embodiment of the present invention, described here, has an active control device AR (dashed line in FIG. 6). The active control device AR shown in FIG. 6 essentially comprises a second receiving device 200 and a comparator unit 301.

The receiving device 200 has a first reference signal input unit 202 for inputting a first reference signal 201, a second reference signal input unit 204 for inputting a second reference signal 203, a second differential amplifier unit 205, 206 (described with reference to FIG. 7 in the text which follows) for amplifying a second signal difference 207 between the first reference signal 201 and the second reference signal 203 and a second output unit 208 for outputting the second signal difference, amplified by the second differential amplifier unit 205, 206, between the first reference signal 201 and the second reference signal 203. As in the case of the first receiving device 100, the second receiving device 200 can also be supplied with the control signal 205. For this purpose, the second receiving device 200 has a control terminal S2 via which the operating point of the second receiving device 200 can be adjusted.

The comparator unit 301 has a target value signal input unit 302 for inputting a target value signal 303 and a control signal output unit 304 for outputting the control signal 305 which is supplied to the first receiving device 100 via the control terminal S1 and to the second receiving device 200 via the control terminal S2.

The target value signal 303 is preferably set to a voltage level which corresponds to half the operating voltage of the entire circuit arrangement (i.e. a voltage level Vdd/2). Furthermore, the first reference voltage 201 and the second reference voltage 203 which are supplied to the second receiving device 200 are set to an equal voltage level which also corresponds to the voltage level of the reference signal 103 which is supplied to the first receiving device 100 via its reference signal input unit 104.

The first signal difference 107 output via the first output unit 108 is used as output signal of the circuit arrangement, in such a manner that it represents a digital value which changes between two states in dependence on how the received signal 101 to be processed is located with reference to the reference signal 103.

In contrast, the second signal difference 207 output from the second receiving device 200 via its second output unit 208 is fixed by the circuit arrangement according to the invention since the second receiving device is supplied with two identical reference signals, i.e. the first reference signal 201 and the second reference signal 203. The second signal difference 207 is thus fixed to a value which corresponds to the target value signal 303. The target value signal 303 which is supplied to the comparator unit 301 via its target value signal input terminal 302 is preferably set to a voltage level which corresponds to half the operating voltage of the entire circuit arrangement, i.e. to a voltage level of Vdd/2.

Independently of the first and second reference signals 201, 203 provided, the gate of the output inverter unit 107 is held at such a medium voltage level Vdd/2 in order to be able to operate at an optimum operating point.

FIG. 7 shows the circuit arrangement shown in FIG. 6 as an equivalent circuit consisting of inverters 105, 106, 205, 206, 301 and 109. A dot-dashed line identifies the active control device AR which includes the second receiving device 200 and the comparator unit 301. In this arrangement, the receiving device 200 (see FIG. 6) with the second differential amplifier unit 205, 206 generates an internal reference voltage VGateREF which corresponds to the control variable 305. The receiving device 200 controls the control variable 305 in such a manner that the following applies: V(bOUTREF)=Vdd/2, i.e. that the control signal 305 controls both the first receiving device 100 and the second receiving device 200 into a respective operating point in such a manner that the amplified second signal difference 207 is held at a level of the target value signal 303.

As can be seen from FIG. 7, the receiving device 200 (active control device AR) ensures that the first signal difference 107 (VbOUT) corresponds to half the operating voltage (Vdd/2) when the voltage level of the received signal 101 corresponds to that of the reference signal 103 (see FIG. 6).

In this circuit design, the second signal difference 107, i.e. the voltage signal VbOUT is controlled extremely precisely and the switching point of the output inverter 109 can be set to half the operating voltage Vdd/2 in a simple manner. If the received signal V(IN) drops below the reference voltage V_{REF}, the signal difference 107 (VbOUT) is pulled above Vdd/2 via the received p-FET. In consequence, the output signal 111 (VOUT) is switched to a low level by means of the output inverter 109, the output inverter 109 having its switching point at Vdd/2. When V(IN) rises to a value above V_{REF}, VbOUT, i.e. the first signal difference 107, is pulled below Vdd/2 and, in consequence, the output signal 111 which is output via the output terminal 110 is switched to a high level (VOUT at a high digital level).

It is advantageously possible to provide energy saving for the entire circuit arrangement by means of the following measures:

(i) the internal reference voltage VGateREF does not need to be generated individually for each input terminal but can be divided between an arbitrary number of input terminals (e.g. 4, 8, 16, . . . );

(ii) if the circuit arrangement is in a state in which it is not required that input receiving devices operate (power-down, non-write, . . . ), the control signal 305 (VGateREF) can be separated from the first differential amplifier unit 105; and

(iii) the receiving stage for the reference voltage V_{REF} can be designed by using dimensions which are scaled down, for example each width dimension of the device can be halved. In this state, VGateREF, i.e. the control signal 305 is generated correctly but the current into the V_{REF} stage is reduced to half the value of the current which would flow if the first receiving device 100 and the second receiving device 200 were constructed from identical circuit components.

It is advantageous to arrange the first receiving device 100 and the second receiving device 200 on a common circuit chip.

The target value signal 303 input into the comparator unit 301 can be generated internally in the circuit chip or predetermined externally. The circuit arrangement according to the invention thus becomes independent of fluctuations in the reference voltage supplied to the first receiving device 100 (with regard to fluctuations of the first reference signal 103) and independent of process variations which occur during a production of receiving devices since the first and second receiving devices 100, 200 are produced from identical circuit components in the same process.

Reference is made to the introduction to the description with respect to the conventional circuit arrangements shown in FIGS. 1 to 5.

Although the present invention has been described above by means of preferred illustrative embodiments, it is not restricted to these but can be modified in many ways.

In addition, the invention is not restricted to the possible applications mentioned.

### LIST OF REFERENCE DESIGNATIONS

In the figures, identical reference symbols designate identical or functionally identical components or steps.
100 Receiving device
101 Received signal
102 Received signal input unit
103 Reference signal
104 Reference signal input unit
105, 106 First differential amplifier unit
107 First signal difference
108 First output unit
109 Inverter unit
110 Output terminal
111 Output signal
200 Receiving device
201 First reference signal
202 Reference signal input unit
203 Second reference signal
204 Reference signal input unit
205, 206 Second differential amplifier unit
207 Second signal difference
208 Second output unit
301 Comparator unit
303 Target value signal
305 Control signal
S1 First control terminal
S2 Second control terminal
Vdd/2 Half operating voltage
AR Control device

### DESCRIPTION

Electronic circuit arrangement with active control during the reception of a received electrical signal

The present invention generally relates to circuit arrangements for receiving electrical signals, particularly voltage signals, and for outputting digital signal values which are dependent on the received electrical signals, and specifically relates to a receiver device with active control.

In particular, the invention is directed towards an electronic circuit arrangement for receiving a received electrical signal which has a first receiving device with a received signal input unit for inputting the received electrical signal to be processed, a reference signal input unit for inputting a reference signal, a first reference amplifier unit for amplifying a first signal difference between the received signal and the reference signal and a first output unit for outputting the first signal difference, amplified by the first signal amplifier unit, between the received signal and the reference signal.

During the reception of received electrical signals, the problem occurs that these must be compared very precisely with a reference signal in the electronic receiving device. With the introduction of differential amplifiers for transmitting data with double the data rate (DDR), in particular, receiving devices have become necessary which amplify such transmission signals which occur, for example, in the operation of dynamic random access memories (DRAM). In this context, a received electrical signal is compared with a reference voltage supplied externally, the reference voltage typically being set to half the operating voltage of the electronic circuit arrangement.

FIGS. 1(a) and 1(b) illustrate conventional circuit arrangements of such an input stage. FIG. 1(a) shows a differential amplifier transistor pair T1 and T2 consisting of n-FET (field effect transistors). Furthermore, a current balancing unit consisting of p-FET units is also used for amplification in the circuit arrangement. A gate bias (n-bias) of one n-FET can either be a controlled voltage, where the n-FET then operates as a controlled current source, or can be simply operated by a digital level where the n-FET then only acts as enabling device.

FIG. 1(b) shows a further differential amplifier circuit according to the prior art. In this arrangement, the current source (n-bias) shown in FIG. 1(a) is replaced by a simple resistor R.

The circuit arrangements described above with reference to FIGS. 1(a) and (b) allow input signals IN to be compared with reference signals REF in a simple manner. This provides an inverted bOUT or non-inverted OUT output signal. However, such conventional circuit arrangements as described by means of FIGS. 1(a) and (b) have significant disadvantages. A main disadvantage of the conventional circuit arrangements consists in that when the reference voltage REF drops to a value which is too low, a functionality of the receiving n-FET transistor pairs is impaired. Specifically, the propagation delay for a falling edge, i.e. in the case V(IN)<V_{REF} becomes considerably longer than the delay for a rising edge, i.e. for the case V(IN)>V_{REF}. This results in an unwanted, non-symmetrical behaviour of the receiving device.

It is also disadvantageous that the voltage bOUT which drives the output inverter I (see FIG. 1(a), (b)) is not well defined. The choice of switching point of the output inverter I is therefore extremely critical.

Furthermore, it is inexpedient that variations with respect to the production process, the applied voltages and the temperature range cannot be corrected. In the text which follows, such variations will be called PVT (process/voltage/temperature) variations.

To solve the above-mentioned problems, it has been proposed in the prior art to use a ‘self-biased receiver’ which is illustrated in FIG. 2 and is disclosed in the printed document U.S. Pat. No. 4,937,476. In the circuit arrangement shown in FIG. 2, the input stage consists of an n-FET connected in series with a p-FET, in such a manner that the operation is improved at a low reference voltage V_{REF}. However, the disclosed circuit arrangement has the disadvantage that the output voltage bOUT can deviate from half the operating voltage Vdd/2 even when the input voltage corresponds to the reference voltage, i.e. when V(IN)=V_{REF} applies. The disadvantage thus exists that it is difficult to control the output inverter I in the case of PVT variations.

FIG. 3 shows a further conventional circuit arrangement which is described in the publication “IEEE Journal of Solid-State Circuits, volume 35, No. 2, February 2000, pages 149-162”. This receiver device uses a mixed n- and p-FET receiving stage in order to improve the behaviour at a low reference voltage V_{REF}.

FIG. 4 shows a schematic block diagram of the conventional receiver device. In this arrangement, the input voltage IN is compared with the reference voltage REF in order to obtain an output voltage OUT.

FIG. 5 shows the conventional circuit arrangement in greater detail, the triangles shown identifying amplifier stages and inverters, respectively. The receiver concept shown in FIG. 5 comprises two inverter pairs which operate back to back. If the input voltage V(IN) corresponds to the reference voltage V_{REF}, i.e. if V(IN)=V_{REF} applies, the output voltage bOUT corresponds to the gate voltage VGate, i.e. bOUT=VGate applies.

If then, for example, the received signal of V(IN) exceeds the reference voltage V_{REF}, i.e. if V(IN)>V_{REF}, bOUT decreases and thus the output of the inverter I goes to a high level OUT. Disadvantageously, however, like the “self-biased” receiver described above, the output level bOUT is not precisely defined.

It is an object of the present invention, therefore, to provide a circuit arrangement for receiving a received electrical signal in which process variations, temperature variations, voltage variations and variations in the reference voltage do not have any influence on an output signal output from the electronic circuit arrangement.

This object is achieved by an electronic circuit arrangement for receiving a received electrical signal having the features of patent Claim 1.

Further embodiments of the invention can be obtained from the subclaims.

An essential concept of the invention consists in designing a receiving device for receiving a received electrical input signal in duplicate, wherein a first receiving device compares a received electrical signal to be processed with a reference voltage whilst identical first and second reference signals are supplied to a second receiving device, wherein the operating points both of the first receiving device and of the second receiving device are controlled by the output signal of the second receiving device into one operating point, so that the signal processing provided in the first receiving device operates independently of fluctuations in the reference voltage and/or independently of process, voltage and/or voltage and/or temperature variations (PVT variations).

The first and second receiving devices advantageously consist of identical circuit components having an identical circuit structure.

According to a main aspect of the present invention, the electronic circuit arrangement for receiving a received electrical signal essentially has the following:

a) a first receiving device which includes:

a1) a received signal input unit for inputting the received electrical signal to be processed;

a2) a reference signal input unit for inputting a reference signal;

a3) a first differential amplifier unit for amplifying a first signal difference between the received signal and the reference signal; and

a4) a first output unit for outputting the first signal difference, amplified by the first differential amplifier unit, between the received signal and the reference signal;

b) a second receiving device which includes:

b1) a first reference signal input unit for inputting a first reference signal;

b2) a second reference signal input unit for inputting a second reference signal;

b3) a second differential amplifier unit for amplifying a second signal difference between the first reference signal and the second reference signal, and

b4) a second output unit for outputting the second signal difference, amplified by the second differential amplifier unit, between the first reference signal and the second reference signal, and

c) a comparator unit for comparing the second signal difference, amplified by the second differential amplifier unit, between the first reference signal and the second reference signal with a target value signal and for outputting a control signal in dependence on the comparison,

d) wherein the control signal controls both the first receiving device and the second receiving device into a respective operating point in such a manner that the amplified second signal difference is held at a level of the target value signal.

The subclaims contain further preferred developments of the present invention.

According to a preferred development of the present invention, the received electrical signal to be processed and/or the reference signal are voltage signals. It is also advantageous that the first reference signal and the second reference signal are voltage signals.

According to a further preferred development of the present invention, the first receiving device and the second receiving device are constructed identically from identical circuit components.

A preferred operation of the circuit arrangement according to the invention is carried out in such a manner that the reference signal, the first reference signal and the second reference signal are identical.

According to another preferred development of the present invention, a target value signal of a voltage level of half the operating voltage Vdd/2 of the electronic circuit arrangement is predetermined for the comparator unit for comparing the second signal difference, amplified by the second differential amplifier unit, between the first reference signal and the second reference signal with the target value signal.

According to a further preferred development of the present invention, the first receiving device and the second receiving device, which are constructed identically from identical circuit components, are arranged on a common circuit chip.

It is advantageous if the reference signal, the first reference signal and/or the second reference signal have a voltage level of half the operating voltage Vdd/2 of the electronic circuit arrangement.

In the text which follows, an illustrative embodiment of the present invention will be described with reference to the drawings, in which:

FIG. 1(a) shows a conventional differential amplifier arrangement with an n-FET differential amplifier transistor pair, using a current balancing circuit;

FIG. 1(b) is a conventional circuit arrangement in which the current balancing circuit is replaced by a resistor;

FIG. 2 is an example of a conventional “self-biased” receiver;

FIG. 3 is a receiver device with a mixed n- and p-FET receiving stage;

FIG. 4 is a schematic block diagram of the receiver device shown in FIG. 3;

FIG. 5 is a circuit equivalence diagram consisting of inverters for the receiver device shown in FIG. 3;

FIG. 6 is a circuit arrangement according to the invention for receiving a received electrical signal according to a preferred illustrative embodiment of the present invention; and

FIG. 7 is an equivalence circuit diagram consisting of inverters for the circuit arrangement shown in FIG. 6.

In the figures, identical reference symbols designate identical or functionally identical components or steps.

In FIG. 6, a reference symbol 100 designates a first receiving device which has a received signal input unit 102 for inputting a received electrical signal 101 to be processed, a reference signal input unit 104 for inputting a reference signal 103, a first differential amplifier unit 105, 106 (described with reference to FIG. 7 in the text which follows) for amplifying a first signal difference 107 between the received signal 101 and the reference signal 103 and a first output unit 108 for outputting the first signal difference 107, amplified by the first differential amplifier unit 105, 106 between the received signal 101 and the reference signal 103. Furthermore, the first receiving device 100 can be supplied via a control terminal S1 with a control signal 305 for controlling or setting the operating point of the receiving device 100.

According to the invention, the circuit arrangement according to the preferred illustrative embodiment of the present invention, described here, has an active control device AR (dashed line in FIG. 6). The active control device AR shown in FIG. 6 essentially comprises a second receiving device 200 and a comparator unit 301.

The receiving device 200 has a first reference signal input unit 202 for inputting a first reference signal 201, a second reference signal input unit 204 for inputting a second reference signal 203, a second differential amplifier unit 205, 206 (described with reference to FIG. 7 in the text which follows) for amplifying a second signal difference 207 between the first reference signal 201 and the second reference signal 203 and a second output unit 208 for outputting the second signal difference, amplified by the second differential amplifier unit 205, 206, between the first reference signal 201 and the second reference signal 203. As in the case of the first receiving device 100, the second receiving device 200 can also be supplied with the control signal 205. For this purpose, the second receiving device 200 has a control terminal S2 via which the operating point of the second receiving device 200 can be adjusted.

The comparator unit 301 has a target value signal input unit 302 for inputting a target value signal 303 and a control signal output unit 304 for outputting the control signal 305 which is supplied to the first receiving device 100 via the control terminal S1 and to the second receiving device 200 via the control terminal S2.

The target value signal 303 is preferably set to a voltage level which corresponds to half the operating voltage of the entire circuit arrangement (i.e. a voltage level Vdd/2). Furthermore, the first reference voltage 201 and the second reference voltage 203 which are supplied to the second receiving device 200 are set to an equal voltage level which also corresponds to the voltage level of the reference signal 103 which is supplied to the first receiving device 100 via its reference signal input unit 104.

The first signal difference 107 output via the first output unit 108 is used as output signal of the circuit arrangement, in such a manner that it represents a digital value which changes between two states in dependence on how the received signal 101 to be processed is located with reference to the reference signal 103.

In contrast, the second signal difference 207 output from the second receiving device 200 via its second output unit 208 is fixed by the circuit arrangement according to the invention since the second receiving device is supplied with two identical reference signals, i.e. the first reference signal 201 and the second reference signal 203. The second signal difference 207 is thus fixed to a value which corresponds to the target value signal 303. The target value signal 303 which is supplied to the comparator unit 301 via its target value signal input terminal 302 is preferably set to a voltage level which corresponds to half the operating voltage of the entire circuit arrangement, i.e. to a voltage level of Vdd/2.

Independently of the first and second reference signals 201, 203 provided, the gate of the output inverter unit 107 is held at such a medium voltage level Vdd/2 in order to be able to operate at an optimum operating point.

FIG. 7 shows the circuit arrangement shown in FIG. 6 as an equivalent circuit consisting of inverters 105, 106, 205, 206, 301 and 109. A dot-dashed line identifies the active control device AR which includes the second receiving device 200 and the comparator unit 301. In this arrangement, the receiving device 200 (see FIG. 6) with the second differential amplifier unit 205, 206 generates an internal reference voltage VGateREF which corresponds to the control variable 305. The receiving device 200 controls the control variable 305 in such a manner that the following applies: V(bOUTREF)=Vdd/2, i.e. that the control signal 305 controls both the first receiving device 100 and the second receiving device 200 into a respective operating point in such a manner that the amplified second signal difference 207 is held at a level of the target value signal 303.

As can be seen from FIG. 7, the receiving device 200 (active control device AR) ensures that the first signal difference 107 (VbOUT) corresponds to half the operating voltage (Vdd/2) when the voltage level of the received signal 101 corresponds to that of the reference signal 103 (see FIG. 6).

In this circuit design, the second signal difference 107, i.e. the voltage signal VbOUT is controlled extremely precisely and the switching point of the output inverter 109 can be set to half the operating voltage Vdd/2 in a simple manner. If the received signal V(IN) drops below the reference voltage V_{REF}, the signal difference 107 (VbOUT) is pulled above Vdd/2 via the received p-FET. In consequence, the output signal 111 (VOUT) is switched to a low level by means of the output inverter 109, the output inverter 109 having its switching point at Vdd/2. When V(IN) rises to a value above V_{REF}, VbOUT, i.e. the first signal difference 107, is pulled below Vdd/2 and, in consequence, the output signal 111 which is output via the output terminal 110 is switched to a high level (VOUT at a high digital level).

It is advantageously possible to provide energy saving for the entire circuit arrangement by means of the following measures:

(i) the internal reference voltage VGateREF does not need to be generated individually for each input terminal but can be divided between an arbitrary number of input terminals (e.g. 4, 8, 16, . . . );

(ii) if the circuit arrangement is in a state in which it is not required that input receiving devices operate (power-down, non-write, . . . ), the control signal 305 (VGateREF) can be separated from the first differential amplifier unit 105; and

(iii) the receiving stage for the reference voltage V_{REF} can be designed by using dimensions which are scaled down, for example each width dimension of the device can be halved. In this state, VGateREF, i.e. the control signal 305 is generated correctly but the current into the V_{REF} stage is reduced to half the value of the current which would flow if the first receiving device 100 and the second receiving device 200 were constructed from identical circuit components.

It is advantageous to arrange the first receiving device 100 and the second receiving device 200 on a common circuit chip.

The target value signal 303 input into the comparator unit 301 can be generated internally in the circuit chip or predetermined externally. The circuit arrangement according to the invention thus becomes independent of fluctuations in the reference voltage supplied to the first receiving device 100 (with regard to fluctuations of the first reference signal 103) and independent of process variations which occur during a production of receiving devices since the first and second receiving devices 100, 200 are produced from identical circuit components in the same process.

Reference is made to the introduction to the description with respect to the conventional circuit arrangements shown in FIGS. 1 to 5.

Although the present invention has been described above by means of preferred illustrative embodiments, it is not restricted to these but can be modified in many ways.

In addition, the invention is not restricted to the possible applications mentioned.

### LIST OF REFERENCE DESIGNATIONS

In the figures, identical reference symbols designate identical or functionally identical components or steps.
100 Receiving device
101 Received signal
102 Received signal input unit
103 Reference signal
104 Reference signal input unit
105, 106 First differential amplifier unit
107 First signal difference
108 First output unit
109 Inverter unit
110 Output terminal
111 Output signal
200 Receiving device
201 First reference signal
202 Reference signal input unit
203 Second reference signal
204 Reference signal input unit
205, 206 Second differential amplifier unit
207 Second signal difference
208 Second output unit
301 Comparator unit
303 Target value signal
305 Control signal
S1 First control terminal
S2 Second control terminal
Vdd/2 Half operating voltage
AR Control device

1. Electronic circuit arrangement for receiving a received electrical signal (101), comprising:
a) a first receiving device (100) which includes:
a1) a received signal input unit (102) for inputting the received electrical signal (101) to be processed;
a2) a reference signal input unit (104) for inputting a reference signal (103);
a3) a first differential amplifier unit (105, 106) for amplifying a first signal difference (107) between the received signal (101) and the reference signal (103); and
a4) a first output unit (108) for outputting the first signal difference (107), amplified by the first differential amplifier unit (105, 106), between the received signal (101) and the reference signal (103);
characterized in that the electronic circuit arrangement furthermore comprises:
b) a second receiving device (200) which includes:
b1) a first reference signal input unit (202) for inputting a first reference signal (201);
b2) a second reference signal input unit (204) for inputting a second reference signal (203),
b3) a second differential amplifier unit (205, 206) for amplifying a second signal difference (207) between the first reference signal (201) and the second reference signal (203); and
b4) a second output unit (208) for outputting the second signal difference (207), amplified by the second differential amplifier unit (205, 206), between the first reference signal (201) and the second reference signal (203);
and
c) a comparator unit (301) for comparing the second signal difference (207), amplified by the second differential amplifier unit (205, 206), between the first reference signal (201) and the second reference signal (203) with a target value signal (303) and for outputting a control signal (305) in dependence on the comparison,
d) wherein the control signal (305) controls both the first receiving device (100) and the second receiving device (200) into a respective operating point in such a manner that the amplified second signal difference (207) is held at a level of the target value signal (303).

2. Circuit arrangement according to claim 1, characterized in that the received electrical signal (101) to be processed and/or the reference signal (103) are voltage signals.

3. Circuit arrangement according to claim 1 or 2, characterized in that the first reference signal (201) and the second reference signal (203) are voltage signals.

4. Circuit arrangement according to claim 1, characterized in that the first receiving device (100) and the second receiving device (200) are constructed identically from identical circuit components.

5. Circuit arrangement according to claim 1, 2 or 3, characterized in that the reference signal (103), the first reference signal (201) and the second reference signal (203) are identical.

6. Circuit arrangement according to claim 1, characterized in that a target value signal of a voltage level of half the operating voltage (Vdd/2) of the electronic circuit arrangement is predetermined for the comparator unit (301) for comparing the second signal difference (207), amplified by the second differential amplifier unit (205, 206), between the first reference signal (201) and the second reference signal (203) with the target value signal (303).

7. Circuit arrangement according to claim 4, characterized in that the first receiving device (100) and the second receiving device (200), which are constructed identically from identical circuit components are arranged on a common circuit chip.

8. Circuit arrangement according to claim 5, characterized in that the reference signal (103), the first reference signal (201) and the second reference signal (203) have a voltage level of half the operating voltage (Vdd/2) of the electronic circuit arrangement.

1. Electronic circuit arrangement for receiving a received electrical signal (101), comprising:
a) a first receiving device (100) which includes:
a1) a received signal input unit (102) for inputting the received electrical signal (101) to be processed;
a2) a reference signal input unit (104) for inputting a reference signal (103);
a3) a first differential amplifier unit (105, 106) for amplifying a first signal difference (107) between the received signal (101) and the reference signal (103); and
a4) a first output unit (108) for outputting the first signal difference (107), amplified by the first differential amplifier unit (105, 106), between the received signal (101) and the reference signal (103);
characterized in that the electronic circuit arrangement furthermore comprises:
b) a second receiving device (200) which includes:
b1) a first reference signal input unit (202) for inputting a first reference signal (201);
b2) a second reference signal input unit (204) for inputting a second reference signal (203),
b3) a second differential amplifier unit (205, 206) for amplifying a second signal difference (207) between the first reference signal (201) and the second reference signal (203); and
b4) a second output unit (208) for outputting the second signal difference (207), amplified by the second differential amplifier unit (205, 206), between the first reference signal (201) and the second reference signal (203);
and
c) a comparator unit (301) for comparing the second signal difference (207), amplified by the second differential amplifier unit (205, 206), between the first reference signal (201) and the second reference signal (203) with a target value signal (303) and for outputting a control signal (305) in dependence on the comparison,
d) wherein the control signal (305) controls both the first receiving device (100) and the second receiving device (200) into a respective operating point in such a manner that the amplified second signal difference (207) is held at a level of the target value signal (303),
wherein
the reference signal (103), the first reference signal (201) and the second reference signal (203) are identical.

2. Circuit arrangement according to claim 1, characterized in that the received electrical signal (101) to be processed and/or the reference signal (103) are voltage signals.

3. Circuit arrangement according to claim 1 or 2, characterized in that the first reference signal (201) and the second reference signal (203) are voltage signals.

4. Circuit arrangement according to claim 1, characterized in that the first receiving device (100) and the second receiving device (200) are constructed identically from identical circuit components.

5. Circuit arrangement according to claim 1, characterized in that a target value signal of a voltage level of half the operating voltage (Vdd/2) of the electronic circuit arrangement is predetermined for the comparator unit (301) for comparing the second signal difference (207), amplified by the second differential amplifier unit (205, 206), between the first reference signal (201) and the second reference signal (203) with the target value signal (303).

6. Circuit arrangement according to claim 4, characterized in that the first receiving device (100) and the second receiving device (200), which are constructed identically from identical circuit components are arranged on a common circuit chip.

7. Circuit arrangement according to claim 1, characterized in that the reference signal (103), the first reference signal (201) and the second reference signal (203) have a voltage level of half the operating voltage (Vdd/2) of the electronic circuit arrangement.
